(19) United States
(12) Patent Application Publication
(10) Pub. No.: US 2019/0111800 A1
(43) Pub. Date: Apr. 18, 2019

(54) HIGH COVERAGE BATTERY USAGE MONITOR

(71) Applicants: Neapco Intellectual Property Holdings, LLC, Farmington Hills, MI (US); Aware Mobility LLC, Ann Arbor, MI (US)

(72) Inventors: Donald Remboski, Ann Arbor, MI (US); Jacqueline Dedo, Wolverine Lake, MI (US)

(21) Appl. No.: 16/160,102

(22) Filed: Oct. 15, 2018

Related U.S. Application Data
(60) Provisional application No. 62/572,734, filed on Oct. 16, 2017.

(51) Int. Cl. B60L 11/18; G01R 31/36; H01M 10/42; H01M 10/48

(52) U.S. Cl. CPC B60L 11/1857; B60L 11/1862; G01R 31/3606; H01M 10/425; G01R 31/3648; B60L 2240/549; H01M 2010/4271; G01R 31/3658; B60L 2240/547; B60L 2240/545; H01M 10/482

(57) ABSTRACT

A method and system for monitoring and controlling a multi-cell battery including a plurality of battery cells uses a battery controller having a processor and a non-transitory computer readable storage medium. A monitoring circuit including current, voltage, and temperature sensors measures a plurality of cell parameters for each of the battery cells, which are communicated to the battery controller. The battery controller performs a parameterization of the cell parameters and past values of the cell parameters to generate a calibrated cell model for each of the battery cells. An optimal usage profile is determined for each of the battery cells as an optimized compromise of cell operating limits between different battery cells within the multi-cell battery, and then causes each of the battery cells to be operated according to the corresponding optimal usage profile. Calculating and reporting of the remaining useful life of the battery is also provided.

### CROSS REFERENCE TO RELATED APPLICATION

This U.S. utility patent application claims the benefit of U.S. provisional patent application No. 62/572,734, filed Oct. 16, 2017, the contents of which are incorporated herein by reference in its entirety.

### BACKGROUND OF THE INVENTION

### 1. Field of the Invention

A system and method for monitoring and controlling a multi-cell battery.

### 2. Description of the Prior Art

Several different types of systems and methods for monitoring and controlling a multi-cell battery exist today. Such systems generally include a controller to cause battery cells within a multi-cell battery to be charged and discharged evenly. It is also known in the art to estimate and preserve battery life based on general usage patterns of the battery.

However, existing solutions fail to fully account for the individual operating conditions of each of the battery cells within a multi-cell battery in order to control use of the battery cells within the cell operating limits and in accordance with an optimal usage profile as determined by a calibrated cell model for each of the battery cells.

### SUMMARY OF THE INVENTION

The subject disclosure includes a monitoring and control method for monitoring and controlling a multi-cell battery. More specifically, the subject disclosure provides for complete monitoring of battery cells in a high-cell-count battery. The subject disclosure also provides for using high-coverage data regarding the battery cells to improve operation, diagnostics, and prognostics of the multi-cell battery.

The method begins by begins by measuring a plurality of cell parameters for each of the battery cells within the multi-cell battery using a monitoring circuit. The method includes communicating the plurality of cell parameters from the monitoring circuit to the battery controller. The method proceeds with the step of recording the measured cell parameters by the battery controller in a non-transitory computer readable storage medium. The method continues with the step of generating a calibrated cell model for each of the battery cells by performing a parameterization of the cell parameters and earlier recorded values of the cell parameters. The method proceeds with the step of determining at least one of a cell safety operating limit and/or a cell life operating limit and/or an optimal usage profile for each of the battery cells using the calibrated cell models for the corresponding ones of the battery cells. The method continues with the step of operating each of the battery cells according to the corresponding cell safety operating limit and/or the corresponding cell life operating limit and/or the corresponding optimal usage profile.

According to an aspect of the disclosure, the calibrated cell model for each of the battery cells is a Randles cell model, which includes values for a series resistance, a double-layer capacitance, and an active charge transfer resistance.

According to another aspect of the disclosure, the method may include determining an associated cell safety operating limit for each of the battery cells using the calibrated cell model for each of the battery cells and operating each of the battery cells within the multi-cell battery to keep each of the battery cells within the associated cell safety operating limit.

According to another aspect of the disclosure, the method may include determining an associated cell life operating limit for each of the battery cells using the calibrated cell model for each of the battery cells and operating each of the battery cells within the multi-cell battery to keep each of the battery cells within the associated cell life operating limit.

According to another aspect of the disclosure, the method may include determining an associated optimal usage profile for each of the battery cells as an optimized compromise of cell operating limits between different ones of the battery cells within the multi-cell battery; and operating each of the battery cells within the multi-cell battery according to the associated optimal usage profile.

More specifically, the step of operating each of the battery cells within the multi-cell battery to keep each of the battery cells within the cell safety operating limits may include commanding for a power controller to limit a voltage and/or an electrical current being supplied to or taken an individual one of the battery cells within the multi-cell battery. Additionally or alternatively, the step of operating each of the battery cells within the multi-cell battery to keep each of the battery cells within the cell safety operating limits may include commanding for a load controller to limit the voltage and/or electrical current being supplied from the multi-cell battery to an electrical load. Additionally or alternatively, the step of operating each of the battery cells within the multi-cell battery may also include commanding for a charging controller to limit at least one of a voltage or an electrical current being supplied to the multi-cell battery.

The subject disclosure also provides a non-transitory computer-readable storage media storing computer-executable instructions that, when executed by a processor, instruct a device to perform various actions. The actions performed as a result of the processor executing the computer-executable instructions include: generating a calibrated cell model for each of a plurality of battery cells within a multi-cell battery by performing a parameterization of cell parameters using values associated with the plurality of cell parameters; determining at least one of a cell safety operating limit, and/or a cell life operating limit, and/or an optimal usage profile for each of the battery cells using the calibrated cell models for the corresponding ones of the battery cells; and operating each of the battery cells according to the at least one of the cell safety operating limit or the cell life operating limit or the optimal usage profile.

According to an aspect of the disclosure, the actions performed as a result of the processor executing the computer-executable instructions may further include: determining a cell safety operating limit for each of the battery cells using the calibrated cell models.

According to an aspect of the disclosure, the actions performed as a result of the processor executing the computer-executable instructions may further include: determining a cell life operating limit for each of the battery cells using the calibrated cell models.

According to an aspect of the disclosure, the actions performed as a result of the processor executing the computer-executable instructions may further include: determining an optimal usage profile for each of the battery cells as an optimized compromise of cell operating limits between different ones of the battery cells within the multi-cell battery.

According to an aspect of the disclosure, the actions performed as a result of the processor executing the computer-executable instructions may include: commanding for a power controller to limit at least one of a voltage or an electrical current being supplied to or taken from a module containing a subset of the battery cells within the multi-cell battery an individual one of the battery cells within the multi-cell battery. Alternatively or additionally, the actions performed as a result of the processor executing the computer-executable instructions may include commanding for a load controller to limit the voltage and/or electrical current being supplied from the multi-cell battery to an electrical load. Alternatively or additionally, the actions performed as a result of the processor executing the computer-executable instructions may include commanding for a charging controller to limit at least one of a voltage or an electrical current being supplied to the multi-cell battery.

The subject disclosure also provides a system for a battery monitor and optimizer. The system includes a multi-cell battery having plurality of battery cells. A monitoring circuit is associated with each of the battery cells and is configured to monitor a plurality of cell parameters of the associated battery cell. The system also includes a battery controller having a processor in communication with the monitoring circuits for generating a calibrated cell model of each of the battery cells. The battery controller is configured to determine at least one of: a cell safety operating limit associated with a high likelihood of damage to an associated one of the battery cells, and/or a cell life operating limit is associated with a reduced service life of the associated one of the battery cells, and/or an optimal usage profile of the associated one of the battery cells. The battery controller is configured to signal a control device to keep the associated one of the battery cells within the cell operating limits or to charge and discharge the associated one of the battery cells in accordance with the optimal usage profile.

In accordance with an aspect of the disclosure, the calibrated cell model for each of the battery cells may be a Randles cell model, which includes values for a series resistance, a double-layer capacitance, and an active charge transfer resistance.

In accordance with an aspect of the disclosure, the control device may include a power controller configured to limit a voltage and/or an electrical current supplied to or taken from a module containing a subset of the battery cells within the multi-cell battery. Alternatively or additionally, the control device may include a load controller configured to limit a voltage and/or an electrical current supplied from the multi-cell battery to an electrical load. Alternatively or additionally, the control device may include a charging controller configured to limit a voltage and/or an electrical current supplied to the multi-cell battery.

Optimization of battery performance and maintaining battery safety often hinges on not overstressing the weakest battery cell in a multi-cell battery, therefore monitoring at the cell level is preferred. By monitoring every individual battery cell, the battery operation can be tailored to avoid damaging the weakest battery cells and therefore improve battery performance and useful life. Individual battery cell monitoring also improves battery safety by identifying cell voltage, current or temperature issues before a cell failure occurs.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a block diagram of a system for monitoring and controlling a multi-cell battery;

FIG. 2 is a schematic diagram of a battery cell;

FIG. 3 is a block diagram of a battery controller;

FIG. 4 is a flow chart illustrating steps for a monitoring and control method according to an aspect of the disclosure;

FIG. 5 is a flow chart illustrating additional steps for the monitoring and control method according to an aspect of the disclosure;

FIG. 6 is a flow chart illustrating steps for a diagnostic method according to an aspect of the disclosure;

FIG. 7 is a flow chart illustrating steps for a prediction method according to an aspect of the disclosure;

FIG. 8 is a flow chart illustrating steps for a status method according to an aspect of the disclosure;

FIG. 9 is a flow chart illustrating alternative steps for the monitoring and control method according to an aspect of the disclosure; and

FIG. 10 is a flow chart illustrating alternative steps for the monitoring and control method according to an aspect of the disclosure.

### DESCRIPTION OF THE ENABLING EMBODIMENT

Referring to the Figures, wherein like numerals indicate corresponding parts throughout the several views, a method 100 and system 10 for monitoring and controlling a multi-cell battery 20 including a plurality of battery cells 22 is provided.

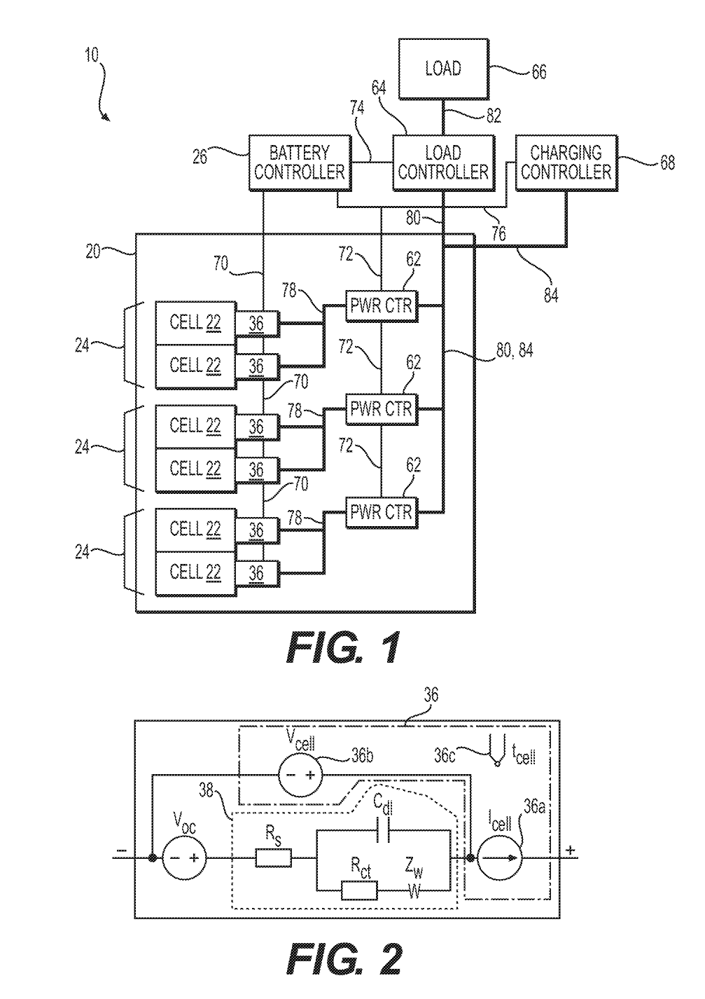

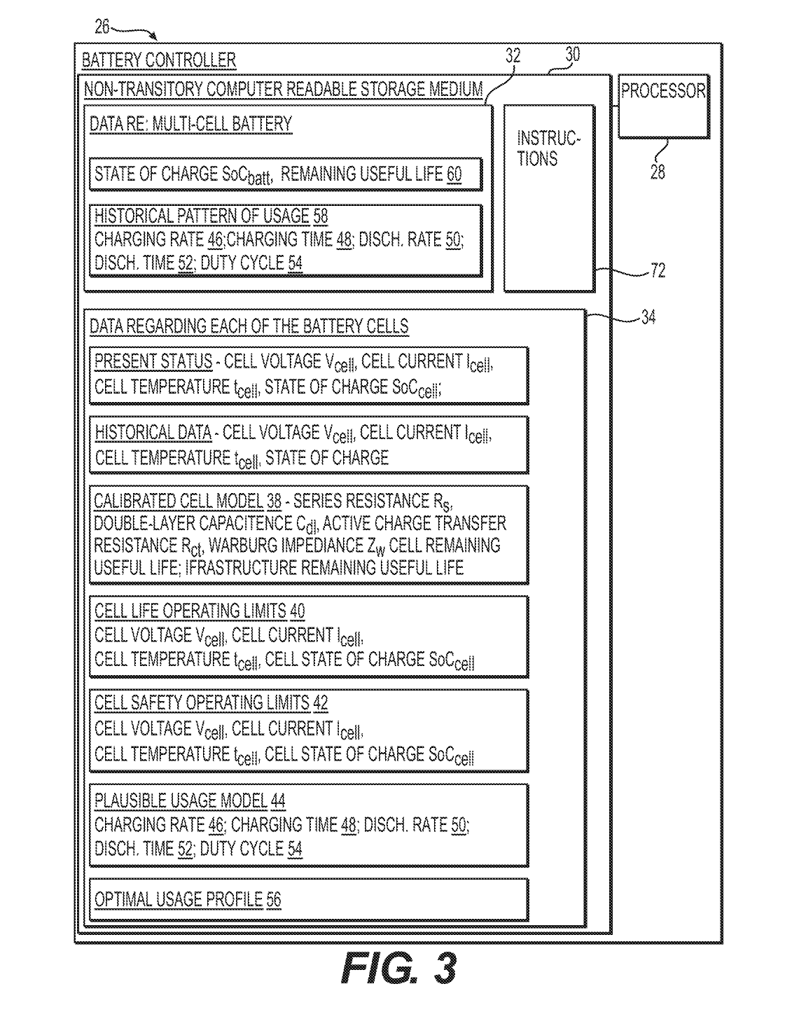

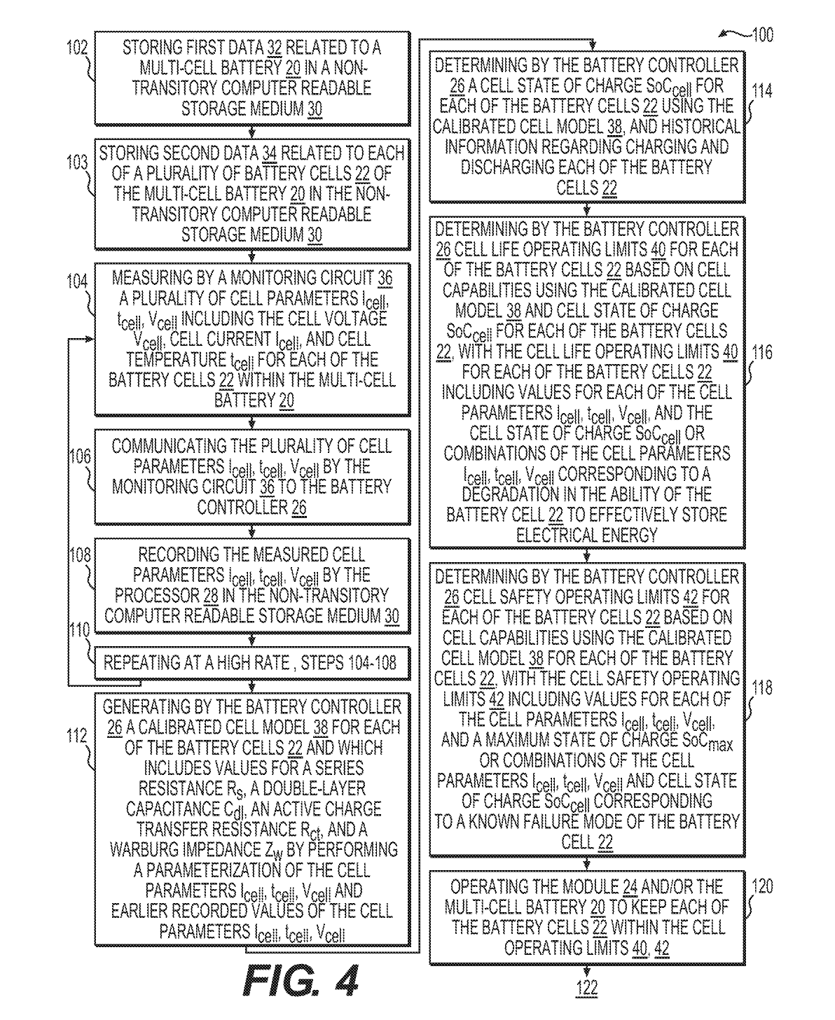

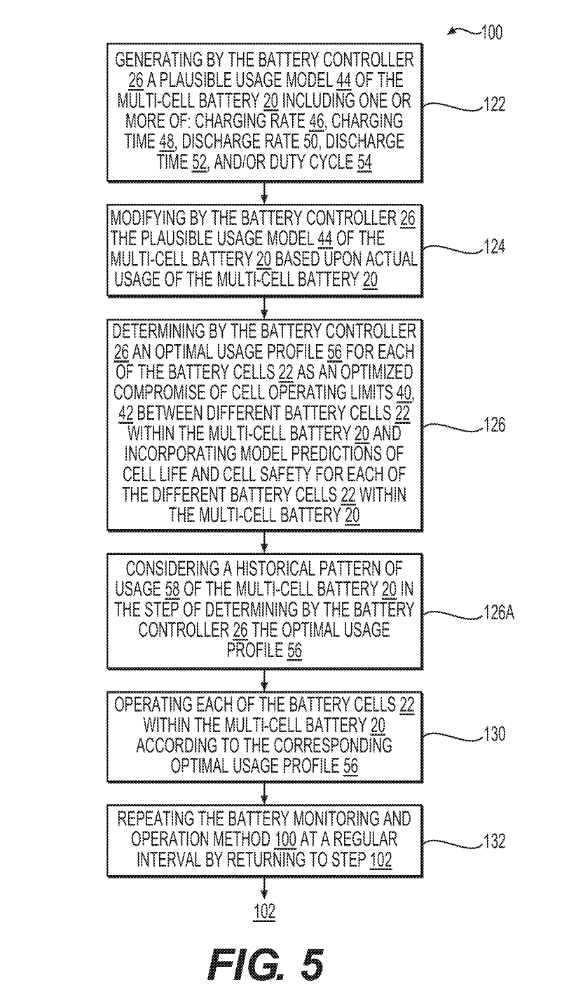

The monitoring and control method 100 for monitoring and controlling a multi-cell battery 20 begins with the step of 102 providing a battery controller 26 including a processor 28 and a non-transitory computer readable storage medium 30 storing battery data 32 related to the multi-cell battery 20 and storing cell data 34 including information related to each of the battery cells 22. One or more of the battery cells 22 may be functionally combined as a module 24. In other words, a module 24 is a subset of the battery cells 22 in the multi-cell battery 20 which are connected in such a way that the parameters can be measured for the module 24 alone. An overview of the system 10 is shown in the block diagram of FIG. 1. FIG. 2 is a schematic diagram of a representative battery cell 22 of the multi-cell battery 20, and FIG. 3 is a block diagram of the battery controller 26.

The method 100 includes 104 measuring values associated with a plurality of cell parameters I_{cell}, t_{cell}, V_{cell} for each of the battery cells 22 within the multi-cell battery 20. The cell parameters including one or more of the cell voltage V_{cell}, cell current I_{cell}, and cell temperature t_{cell}. The values may be measured by a monitoring circuit 36, including a current sensor 36a, a voltage sensor 36b, and a temperature sensor 36c. One or more of the sensors 36a, 36b, 36c may be shared amongst two or more of the battery cells 22. For example, there may be a single, shared temperature sensor 36c for a module of two or more of the battery cells 22. The monitoring circuit 36 may also measure other parameters including, for example, cell capacitance, mass transfer resistance (or charge transfer resistance), and/or relaxation time (e.g. the Warburg impedance Z_{w}) of the battery cell 22. As will be explained in more detail later, monitoring each of the battery cells 22 allows for the battery controller 26 to be aware of the condition of each cell within the multi-cell battery 20, which also allows the multi-cell battery 20 to be controlled during charging and discharging to optimize for several different considerations including, for example, performance and battery life.

The method 100 also includes 106 communicating the values associated with the plurality of cell parameters I_{cell}, t_{cell}, V_{cell} to the battery controller 26. The monitoring circuit 36 or circuits may communicate the values. Alternatively or additionally, another device, such as a module controller associated with a module of two or more of the battery cells 22 may perform this step 106. As illustrated in FIG. 1, a first communications path 70 may be provided between the monitoring circuit 36 and the battery controller 26. Many different types of configurations may be used for the first communications path 70, including wired or wireless communications, electrical, radio, optical (fibre optic or free air). The first communications path 70 may be arranged in any of several different configurations or arrangements including, for example, star topology, daisy-chain, or combinations thereof. According to an aspect, two or more monitoring circuits 36 may be combined into a single functional unit, which may have a single communications path to the battery controller 26. According to another aspect, one or more monitoring circuits 36 may be combined with the battery controller 26 as a functional unit.

The method 100 proceeds with the step of 108 recording the values associated with the plurality of cell parameters I_{cell}, t_{cell}, V_{cell} in the non-transitory computer readable storage medium 30. This step 108 may be performed by the battery controller 26. Specifically, the processor 28 of the battery controller 26 may record the values of the measured cell parameters I_{cell}, t_{cell}, V_{cell} in the non-transitory computer readable storage medium 30 of the battery controller 26. Alternatively or additionally, one or more other controllers, such as a data logger may record the values of the measured cell parameters I_{cell}, t_{cell}, V_{cell}.

Different values of the measured cell parameters I_{cell}, t_{cell}, V_{cell} recorded at different times 48, 52 may also be retained in the non-transitory computer readable storage medium 30. As shown in the block diagram of FIG. 3, the recorded values of the measured cell parameters I_{cell}, t_{cell}, V_{cell} may be stored in a cell data 34 area of a non-transitory computer readable storage medium 30 within the battery controller 26. The measured cell parameters I_{cell}, t_{cell}, V_{cell} may alternatively be stored in another location and/or in a distributed manner between multiple different locations. Some or all of the recorded values of the measured cell parameters I_{cell}, t_{cell}, V_{cell} may be stored locally, such as within a memory of the battery controller 26. According to an aspect, some or all of the recorded values of the measured cell parameters I_{cell}, t_{cell}, V_{cell} may be stored remotely. For example, the system 10 may be configured to store the previous minute worth of the measured values of the cell parameters I_{cell}, t_{cell}, V_{cell} locally, within the non-transitory computer readable storage medium 30 of the battery controller 26. The system 10 may also store more extensive historical values of the cell parameters I_{cell}, t_{cell}, V_{cell} in a remote server and/or in a distributed fashion (i.e. in “the cloud”).

The method 100 includes 110 repeating, at a high rate, steps 104-108 for each of the battery cells 22. For example, the cell parameters I_{cell}, t_{cell} V_{cell} may be measured and recorded (i.e. sampled) at a rate of 1 to 1000 samples per second.

The method 100 continues with the step of 112 generating by the battery controller 26 a calibrated cell model 38 for each of the battery cells 22 by performing a parameterization of the cell parameters I_{cell}, t_{cell}, V_{cell} using the current values of those cell parameters I_{cell}, t_{cell}, V_{cell} and/or earlier recorded values of the cell parameters I_{cell}, t_{cell}, V_{cell}. Algorithms for parameter identification (i.e. parameterization) may be entirely empirical learning mechanisms (e.g. neural network) or may be curve fitting (least squares) or optimal (Kalman, LQE) curve fitting to structured physical models. As illustrated in FIG. 2, the calibrated cell model 38 may take the form of an electrical model. In particular, the calibrated cell model 38 may include an open circuit voltage V_{oc}. The calibrated cell model 38 may also include a Randles cell model, including values for a series resistance Rₛ, a double-layer capacitance C_{dl}, an active charge transfer resistance Rₑₜ, and a Warburg impedance Z_{w}. The Warburg impedance Z_{w} may alternatively be categorized as a mass transfer resistance (or charge transfer resistance) or as a relaxation time. The calibrated cell model 38 may include other physical parameters of interest regarding the battery cell 22 such as, for example, cell source voltage as a function of current (not necessarily a linear relationship), ohmic series resistance, series and parallel capacitance, and inductance. These determinations may be for individual battery cells 22 within the multi-cell battery, or may be made for a population of battery cells across many different batteries, such as, for example, using data in a distributed computing and storage facility (i.e. in “the cloud”). The calibrated cell model 38 may also include an electrochemical model of the battery cell 22. The calibrated cell model 38 may include information on the relative strength (or weakness) of the battery cell 22.

The method 100 proceeds with the step of 114 determining by the battery controller 26 a cell state of charge SoC_{cell} for each of the battery cells 22. The processor 28 may use the calibrated cell model 38, and historical information regarding charging and discharging each of the battery cells 22 in determining the cell state of charge SoC_{cell}.

The method 100 proceeds with the step of 116 determining by the battery controller 26 cell life operating limits 40 for each of the battery cells 22. The cell life operating limits 40 may include values such as a temperature, current, voltage, or a combination thereof that is associated with a reduction in the service life and/or the storage capacity of the associated battery cell 22. In determining the cell life operating limits 40, the processor 28 may determine cell capabilities using the calibrated cell model 38 and the cell state of charge SoC_{cell}. The cell life operating limits 40 for each of the battery cells 22 may include values for each of the cell parameters I_{cell}, t_{cell}, V_{cell}, or combinations of the cell parameters I_{cell}, t_{cell}, V_{cell} and cell state of charge SoC_{cell} corresponding to a degradation in the ability of the battery cell 22 to effectively store electrical energy.

The method 100 proceeds with the step of 118 determining cell safety operating limits 42 for each of the battery cells 22. The cell safety operating limits 42 may include values such as a temperature, current, voltage, or a combination thereof that is associated with a high likelihood of damage to the associated battery cell 22. This step 118 may be performed by the battery controller 26. In determining the cell safety operating limits 42, the processor 28 may determine cell capabilities using the calibrated cell model 38 for each of the battery cells 22, with the cell safety operating limits 42 including values for each of the cell parameters I_{cell}, t_{cell}, V_{cell}, and a maximum state of charge SoCₘₐₓ or combinations of the cell parameters I_{cell}, t_{cell}, V_{cell} and cell state of charge SoC_{cell} corresponding to a known failure mode of the battery cell 22.

The method 100 continues with the step of 120 operating the module 24 and/or the multi-cell battery 20 to keep each of the battery cells 22 within the cell operating limits 40, 42. As will be explained in more detail below, the system 10 may include one or more different control devices 62, 64, 68 to control the flow of electrical energy and to keep each of the battery cells 22 within the cell operating limits 40, 42.

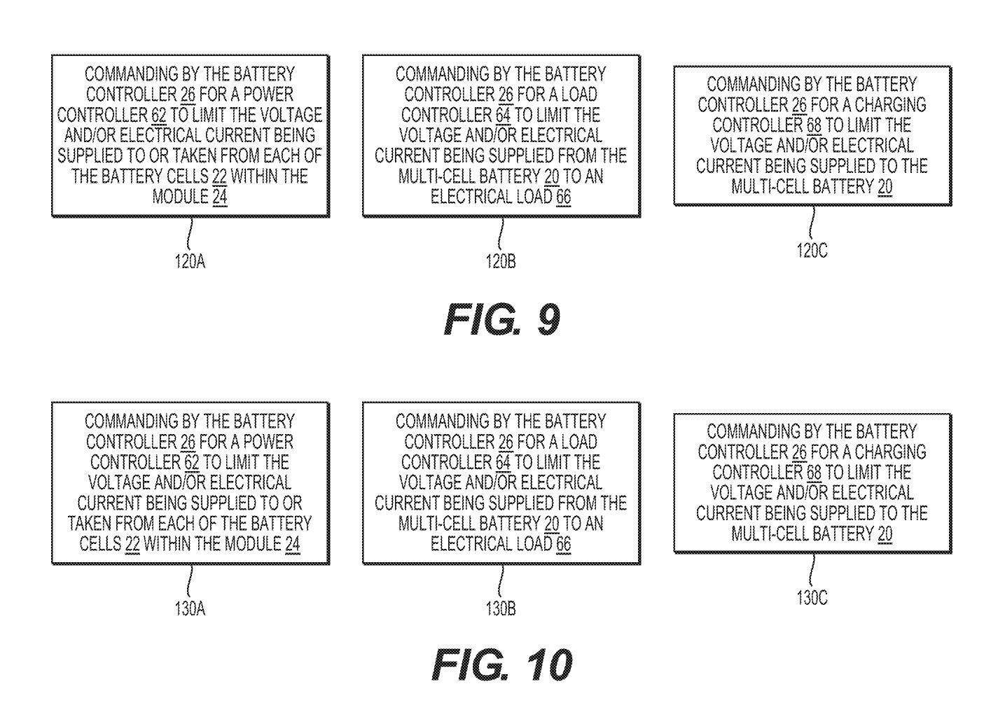

According to an aspect, and as illustrated in FIG. 9, the step of 120 operating the module 24 and/or the multi-cell battery 20 to keep each of the battery cells 22 within the cell operating limits 40, 42, may include 120A commanding by the battery controller 26 for a power controller 62 to limit the voltage and/or electrical current being supplied to or taken from individual ones of the battery cells 22. Each module 24 of two or more battery cells 22 may include an associated power controller 62, which may be configured to limit the voltage and/or electrical current being supplied to or taken from individual ones of the battery cells 22 within that module.

According to an aspect, and as illustrated in FIG. 9, the step of 120 operating the module 24 and/or the multi-cell battery 20 to keep each of the battery cells 22 within the cell operating limits 40, 42 may include 120B commanding by the battery controller 26 for a load controller 64 to limit the voltage and/or electrical current being supplied from the multi-cell battery 20 to an electrical load 66.

According to an aspect, and as illustrated in FIG. 9, the step of 120 operating the module 24 and/or the multi-cell battery 20 to keep each of the battery cells 22 within the cell operating limits 40, 42 may include 120C commanding by the battery controller 26 for a charging controller 68 to limit the voltage and/or electrical current being supplied to the multi-cell battery 20. The charging controller 68 may be located onboard the vehicle, or at a stationary location such as a charger for Level 1, 2, or 3 charging from an AC or a DC power source. The charging controller 68 may include components that are both onboard the vehicle and located elsewhere, such as at a stationary location. Other devices, such as a motor controller acting as a power source in a regenerative braking mode, may function as the charging controller 68 for the purpose of performing this step 120C.

The method 100 continues with the step of 122 generating by the battery controller 26 a plausible usage model 44 of the multi-cell battery 20 including one or more of: charging rate 46, charging time 48, discharge rate 50, discharge time 52, and/or duty cycle 54. The plausible usage model 44 may incorporate details regarding charging, discharging, or a combination thereof. The plausible usage model 44 may include details regarding the duty cycle 54 of either or both of charging and/or discharging the multi-cell battery 20. The method 100 may include 124 modifying by the battery controller 26 the plausible usage model 44 of the multi-cell battery 20 based upon actual usage of the multi-cell battery 20. Such actual usage may be impacted, for example, by driver habits (for vehicular applications).

The method 100 proceeds with the step of 126 determining an optimal usage profile 56 for each of the battery cells 22 based on an optimized compromise of cell operating limits 40, 42 between different battery cells 22 within the multi-cell battery 20. This step 126 may be performed by the battery controller 26 and may take into account model predictions of cell life and cell safety for each of the different battery cells 22 within the multi-cell battery 20. For example, if a battery cell 22 is exhibiting an increased series resistance Rₛ, and the attendant heating that occurs when charging or discharging at a high rate (i.e. with a high cell current I_{cell}), then the optimal usage profile 56 will exclude or limit that cell from charging or discharging at high current to ensure that the battery cell 22 does not overheat and create a safety hazard. As another example, if a battery cell 22 is exhibiting a loss of charge storage capacity that is aggravated or increased by deep discharge and recharge cycles, the optimal usage profile 56 may limit discharge depth of that particular battery cell 22 in order to maintain battery function for a longer period of time. This deration of battery capability may be accompanied by notification to the battery's user of the de-rated battery performance.

According to an aspect, the method 100 may also include the step of 128 including a historical pattern of usage 58 of the multi-cell battery 20 in the step of 126 determining the optimal usage profile 56. For example, discharge depth of individual cells may be subjected to a lesser limitation in a multi-cell battery 20 that is rarely deeply discharged. As another example, for a battery that usually sees low duty-cycle operation including low usage time and long recharge time, the system 10 may allow weaker cells to recharge at a relatively slow rate, particular where those weaker cells are likely to be degraded by being rapidly recharged.

The method 100 continues with the step of 130 operating each of the battery cells 22 within the multi-cell battery 20 according to the corresponding optimal usage profile 56. As will be explained in more detail below, the system 10 may include one or more different control devices 62, 64, 68 to control the flow of electrical energy and to charge and discharge each of the battery cells 22 according to the optimal usage profile 56. The overall goal is to maintain the best battery life while still providing adequate charge storage and power capacity.

According to an aspect, and as illustrated in FIG. 10, the step of 130 operating each of the battery cells 22 within the multi-cell battery 20 according to the corresponding optimal usage profile 56 may include 130A commanding by the battery controller 26 for a power controller 62 to limit the voltage and/or electrical current being supplied to or taken from each of the battery cells 22 associated with the module 24. This may include, for example, limiting charging and/or discharging rate of the multi-cell battery 20.

According to an aspect, and as illustrated in FIG. 10, the step of 130 operating each of the battery cells 22 within the multi-cell battery 20 according to the corresponding optimal usage profile 56 may include 130B commanding by the battery controller 26 for a load controller 64 to limit the voltage and/or electrical current being supplied from the multi-cell battery 20 to an electrical load 66.

According to an aspect, and as illustrated in FIG. 10, the step of 130 operating each of the battery cells 22 within the multi-cell battery 20 according to the corresponding optimal usage profile 56 may include 130C commanding by the battery controller 26 for a charging controller 68 to limit the voltage and/or electrical current being supplied to the multi-cell battery 20.

The method 100 continues with the step of 132 repeating the method 100 at a regular interval by returning back to step 102. In other words, the method 100 may continuously cycle. The processor 28 may cause the method 100 to cycle at regular intervals. According to an aspect, the method 100 may only be active while the multi-cell battery 20 is actively charging or discharging. Alternatively, the method 100 may always be active.

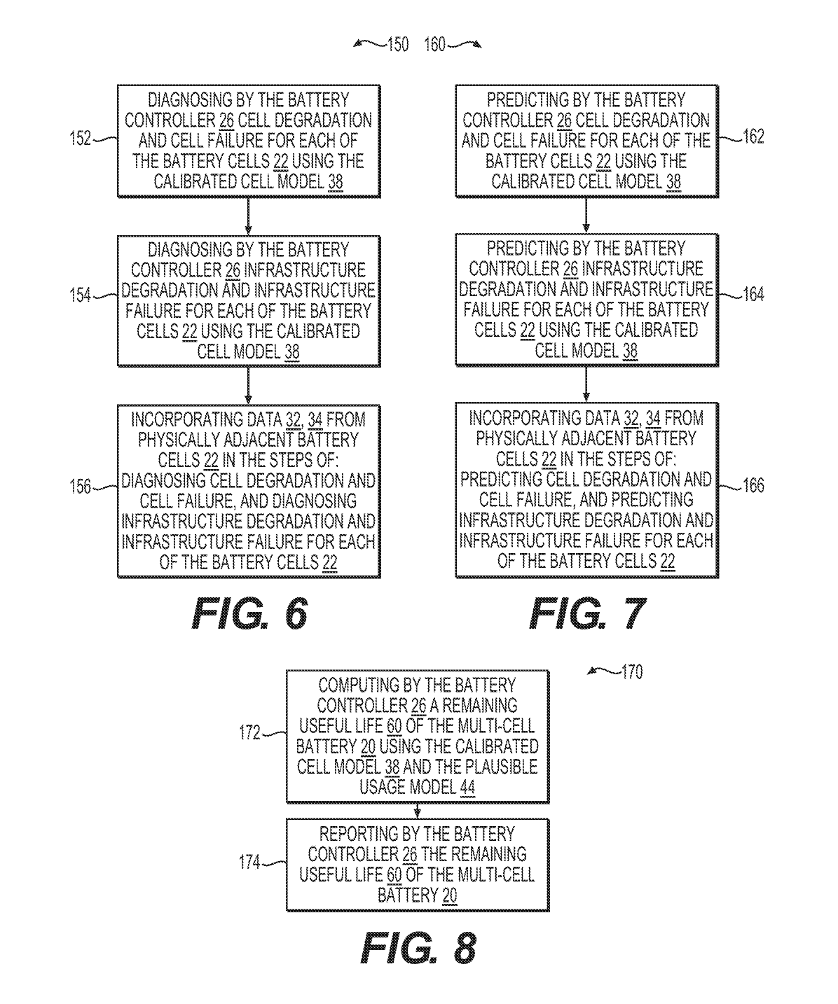

As illustrated in the flow chart of FIG. 6, a diagnostic method 150 may be provided for diagnosing conditions within the multi-cell battery 20. The diagnostic method 150 may include 152 diagnosing by the battery controller 26 cell degradation and cell failure for each of the battery cells 22 using the calibrated cell model 38. In diagnosing degradation and cell failure, the battery controller 26 may use physical models of cell performance, statistical process control type limit calculations, or other means, or a combination of different methods. The diagnostic method 150 may also include 154 diagnosing by the battery controller 26 infrastructure degradation and infrastructure failure for each of the battery cells 22 using the calibrated cell model 38. Such infrastructure degradation may include, for example, reduced capacity in cooling the multi-cell battery 20 and/or reduced capacity to conduct electrical power between battery cells 22 and/or to and from the multi-cell battery 20, such as may result, for example, from corrosion of one or more of the electrical conductors 78, 80, 82, 84.

The diagnostic method 150 may also include 156 incorporating data from physically adjacent battery cells 22 in performing steps 152-154 for each of the battery cells 22. For example, excessive physical vibration or excessive temperature may be a local phenomenon in the multi-cell battery 20 due to structure failure or thermal management system failure. These failures may show up in cell monitor data for several different battery cells 22 in the affected regions. In other words, the system 10 provides for diagnosing local electrical, mechanical or thermal problems in one region of the battery by observing the change in temperature, voltage or current on a cell-by-cell basis.

As illustrated in the flow chart of FIG. 7, a prediction method 160 may be provided for predicting future conditions within the multi-cell battery 20. The prediction method 160 may include 162 predicting by the battery controller 26 cell degradation and cell failure for each of the battery cells 22 using the calibrated cell model 38. In predicting degradation and cell failure, the battery controller 26 may use physical models of cell performance, statistical process control type limit calculations, or other means, or a combination of different methods. The prediction method 160 may also include 164 predicting by the battery controller 26 infrastructure degradation and infrastructure failure for each of the battery cells 22 using the calibrated cell model 38. Like the diagnostic method 150, the prediction method 160 may also include 166 incorporating data from physically adjacent battery cells 22 in performing steps 162-164.

As illustrated in the flow chart of FIG. 8, a status method 170 may be provided that includes the steps of 172 computing by the battery controller 26 a remaining useful life 60 of the multi-cell battery 20 using the calibrated cell model 38 and the plausible usage model 44. The status method 170 also includes 174 reporting by the battery controller 26 the remaining useful life 60 of the multi-cell battery 20. The remaining useful life 60 may be reported to interested persons such as users, vehicle owners, vehicle fleet operators, vehicle OEMs, and/or maintainers of the multi-cell battery 20. The remaining useful life 60 may be reported in one or more of several different formats, such as a percent of “new” or nominal, a time or distance of remaining useful life 60, such as X months and/or Y years remaining. The remaining useful life 60 may also be reported as a distance range that the vehicle can travel with the multi-cell battery 20 at full charge. The reporting may be accomplished using a status display, such as on an instrument cluster of a vehicle. The reporting may be accomplished by transmitting the remaining useful life 60 to a remote monitoring system 10 for presentation and/or for other purposes such as for scheduling preventative maintenance such as repair or replacement of the multi-cell battery 20. An accurate remaining useful life calculation can enable a more accurate vehicle residual value calculation. This enables more accurate pricing of used electric vehicles.

As best shown in FIGS. 1-3, a system 10 for a battery monitor and optimizer is also provided. The system 10 includes a multi-cell battery 20 having plurality of battery cells 22. The battery cells 22 are grouped into modules 24 each having a one or more battery cells 22 that are functionally grouped together. A monitoring circuit 36 is associated with and includes a current sensor 36a, and a voltage sensor 36b, each connected to each of the battery cells 22, as well as a temperature sensor 36c disposed proximate to each of the battery cells 22 for monitoring a plurality of cell parameters I_{cell}, t_{cell}, V_{cell}, including cell voltage V_{cell}, cell current I_{cell}, and cell temperature t_{cell}, of the associated battery cell 22. The battery monitoring system 10 may reside entirely with or near the multi-cell battery 20 or may be distributed across many storage and computing modules such as with cloud computing.

As illustrated in FIG. 1, the system 10 also includes a battery controller 26. As illustrated in FIG. 3, the battery controller 26 includes a non-transitory computer readable storage medium 30 storing battery data 32 including information related to the multi-cell battery 20. The battery data 32 may include, for example, a battery state of charge SoC_{batt}, a remaining useful life 60, and/or values for other parameters such as temperature, voltage, charging or discharging current, etc. The non-transitory computer readable storage medium 30 also stores cell data 34 including information related to each of the battery cells 22. The cell data 34 may include, for example, cell voltage V_{cell}, cell state of charge SOC_{cell}, the cell current I_{cell}, the cell temperature t_{cell}, etc. The battery controller 26 includes a processor 28 in communication with the monitoring circuits 36 via a first communications path 70, and generating a calibrated cell model 38 of each of the battery cells 22 and for signaling a control device 62, 64, 68 to keep the battery cell 22 within the cell operating limits 40, 42.

As illustrated in FIG. 1, a power controller 62 is associated with each of the modules 24, and has a second communications path 72 between the battery controller 26 and the power controller 62 for allowing the battery controller 26 to command each of the power controllers 62 for controlling the delivery of electrical power to and/or from the associated one of the modules 24. A load controller 64 is provided with a third communications path 74 between the battery controller 26 and the load controller 64 for allowing the battery controller 26 to command the load controller 64 to control the delivery of electrical current from the multi-cell battery 20 to an electrical load 66. The load controller 64 may be any device capable of controlling an amount of electrical energy consumed by an electrical load. The load controller 64 may be, for example, an inverter for a motor drive, a heater controller, an air conditioning compressor controller. Likewise, the electrical load 66 may be any device that consumes electrical energy. The electrical load 66 may include, for example, a traction motor, a resistance heater or other HVAC component such as an air compressor or fan blower. The electrical load 66 may also include a DC/DC converter for providing a low-voltage supply, such as 12 VDC, for running accessories and/or for charging a low-voltage battery. A charging controller 68 is also provided with a fourth communications path 76 between the battery controller 26 and the charging controller 68 for allowing the battery controller 26 to command the charging controller 68 to control the delivery of electrical current to charge the multi-cell battery 20.

As also shown in FIG. 1, a first electrical conductor 78 transmits electrical power to the power controllers 62 from associated ones of the modules 24 of battery cells 22. A second electrical conductor 80 transmits electrical power from the power controllers 62 to the load controller 64. A third electrical conductor 82 transmits electrical power from the load controllers 64 to the electrical load 66, and a fourth electrical conductor 84 transmits electrical power from the charging controller 68 to the multi-cell battery 20.

In another aspect, the non-transitory computer-readable storage medium 30 stores computer-executable instructions 72 that, when executed by the processor 28, instruct a device to perform several different actions. The actions performed as a result of the processor 28 executing the computer-executable instructions 72 include generating a calibrated cell model 38 for each of a plurality of battery cells 22 within a multi-cell battery 20 by performing a parameterization of cell parameters I_{cell}, t_{cell}, V_{cell} using values associated with those cell parameters I_{cell}, t_{cell}, V_{cell} and/or earlier recorded values of the cell parameters I_{cell}, t_{cell}, V_{cell}. The actions performed as a result of the processor 28 executing the computer-executable instructions 72 also include determining at least one of a cell safety operating limit 42 or an optimal usage profile 56 for each of the battery cells 22 using the calibrated cell models 38 for the corresponding ones of the battery cells 22. The actions performed as a result of the processor 28 executing the computer-executable instructions 72 also include operating each of the battery cells 22 according to the at least one of the cell safety operating limit 42 and/or the optimal usage profile 56. This may be accomplished as detailed above with reference to the method 100 for monitoring and controlling the multi-cell battery 20. The processor 28, may, for example, signal a control device 62, 64, 68 to keep the battery cells 22 within the associated cell operating limits 40, 42.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure

What is claimed is:

1. A method for monitoring and controlling a multi-cell battery including a plurality of battery cells, comprising the steps of:
measuring by a monitoring circuit, values associated with a plurality of cell parameters for each of the battery cells within the multi-cell battery;
communicating the values associated with the plurality of cell parameters to a battery controller;
recording the values associated with the plurality of cell parameters in a non-transitory computer readable storage medium;
generating a calibrated cell model for each of the battery cells by performing a parameterization of the cell parameters using the values associated with the plurality of cell parameters;
determining at least one of a cell safety operating limit or a cell life operating limit or an optimal usage profile for each of the battery cells using the calibrated cell models for the corresponding ones of the battery cells; and
operating each of the battery cells according to the at least one of the cell safety operating limit or the cell life operating limit or the optimal usage profile.

2. The method for monitoring and controlling a multi-cell battery as set forth in claim 1, wherein the calibrated cell model for each of the battery cells is a Randles cell model including values for a series resistance, a double-layer capacitance, and an active charge transfer resistance.

3. The method for monitoring and controlling a multi-cell battery as set forth in claim 1, wherein the step of determining at least one of a cell safety operating limit or a cell life operating limit or an optimal usage profile for each of the battery cells using the calibrated cell models for the corresponding ones of the battery cells includes:
determining an associated cell safety operating limit for each of the battery cells using the calibrated cell model for each of the battery cells; and
operating each of the battery cells according to the associated cell safety operating limit.

4. The method for monitoring and controlling a multi-cell battery as set forth in claim 1, wherein the step of determining at least one of a cell safety operating limit or a cell life operating limit or an optimal usage profile for each of the battery cells using the calibrated cell models for the corresponding ones of the battery cells includes:
determining an associated cell life operating limit for each of the battery cells using the calibrated cell models for each of the battery cells; and
operating each of the battery cells according to the associated cell life operating limit.

5. The method for monitoring and controlling a multi-cell battery as set forth in claim 1, wherein the step of determining at least one of a cell safety operating limit or a cell life operating limit or an optimal usage profile for each of the battery cells using the calibrated cell models for the corresponding ones of the battery cells includes:
determining an associated optimal usage profile for each of the battery cells as an optimized compromise of cell operating limits between different ones of the battery cells within the multi-cell battery; and
operating each of the battery cells according to the associated optimal usage profile.

6. The method for monitoring and controlling a multi-cell battery as set forth in claim 1, wherein the step of operating each of the battery cells according to the at least one of the cell safety operating limit or the cell life operating limit or the optimal usage profile includes: commanding for a power controller to limit at least one of a voltage or an electrical current being supplied to or taken from an individual one of the battery cells within the multi-cell battery.

7. The method for monitoring and controlling a multi-cell battery as set forth in claim 1, wherein the step of operating each of the battery cells according to the at least one of the cell safety operating limit or the cell life operating limit or the optimal usage profile includes: commanding for a load controller to limit the voltage and/or electrical current being supplied from the multi-cell battery to an electrical load.

8. The method for monitoring and controlling a multi-cell battery as set forth in claim 1, wherein the step of operating each of the battery cells according to the at least one of the cell safety operating limit or the cell life operating limit or the optimal usage profile includes: commanding for a charging controller to limit at least one of a voltage or an electrical current being supplied to the multi-cell battery.

9. A non-transitory computer-readable storage media storing computer-executable instructions that, when executed by a processor, instruct a device to perform actions comprising:
generating a calibrated cell model for each of a plurality of battery cells within a multi-cell battery by performing a parameterization of cell parameters using values associated with the plurality of cell parameters;
determining at least one of a cell safety operating limit or a cell life operating limit or an optimal usage profile for each of the battery cells using the calibrated cell models for the corresponding ones of the battery cells; and
operating each of the battery cells according to the at least one of the cell safety operating limit or the cell life operating limit or the optimal usage profile.

10. The non-transitory computer-readable storage media storing computer-executable instructions as set forth in claim 9, wherein the instructions, when executed by the processor, instruct a device to determine a cell safety operating limit for each of the battery cells using the calibrated cell models.

11. The non-transitory computer-readable storage media storing computer-executable instructions as set forth in claim 9, wherein the instructions, when executed by the processor, instruct a device to determine a cell life operating limit for each of the battery cells using the calibrated cell models.

12. The non-transitory computer-readable storage media storing computer-executable instructions as set forth in claim 9, wherein the instructions, when executed by the processor, instruct a device to determine an optimal usage profile for each of the battery cells as an optimized compromise of cell operating limits between different ones of the battery cells within the multi-cell battery

13. The non-transitory computer-readable storage media storing computer-executable instructions as set forth in claim 9, wherein the instructions, when executed by a processor, instruct a device to perform actions further comprising:
commanding for a power controller to limit at least one of a voltage or an electrical current being supplied to or taken from a module containing a subset of the battery cells within the multi-cell battery an individual one of the battery cells within the multi-cell battery.

14. The non-transitory computer-readable storage media storing computer-executable instructions as set forth in claim 9, wherein the instructions, when executed by a processor, instruct a device to perform actions further comprising:
commanding for a load controller to limit the voltage and/or electrical current being supplied from the multi-cell battery to an electrical load.

15. The non-transitory computer-readable storage media storing computer-executable instructions as set forth in claim 9, wherein the instructions, when executed by a processor, instruct a device to perform actions further comprising:
commanding for a charging controller to limit at least one of a voltage or an electrical current being supplied to the multi-cell battery.

16. A system for a battery monitor and optimizer, comprising:
a multi-cell battery including a plurality of battery cells;
a monitoring circuit associated with each of said battery cells, with each of said monitoring circuits configured to monitor a plurality of cell parameters of an associated one of said battery cells; and
a battery controller including a processor in communication with said monitoring circuits and configured to generate a calibrated cell model of each of said battery cells;
said battery controller configured to determine at least one of a cell safety operating limit associated with a high likelihood of damage to an associated one of the battery cells, or a cell life operating limit is associated with a reduced service life of the associated one of the battery cells, or an optimal usage profile of the associated one of the battery cells;
said battery controller configured to signal a control device to keep the associated one of the battery cells within the cell operating limits or to charge and discharge the associated one of the battery cells in accordance with the optimal usage profile.

17. The system for a battery monitor and optimizer of claim 16, wherein said calibrated cell model for each of the battery cells is a Randles cell model including values for a series resistance, a double-layer capacitance, and an active charge transfer resistance.

18. The system for a battery monitor and optimizer of claim 16, wherein the control device includes a power controller configured to limit at least one of a voltage or an electrical current supplied to or taken from a module containing a subset of the battery cells within the multi-cell battery.

19. The system for a battery monitor and optimizer of claim 16, wherein the control device includes a load controller configured to limit at least one of a voltage or an electrical current supplied from the multi-cell battery to an electrical load.

20. The system for a battery monitor and optimizer of claim 16, wherein the control device includes a charging controller configured to limit at least one of a voltage or an electrical current supplied to the multi-cell battery.
